(19) United States
(12) Patent Application Publication
(10) Pub. No.: US 2026/0144044 A1
(43) Pub. Date: May 21, 2026

(54) SEMICONDUCTOR DEVICE HAVING IRDL PATTERN

(71) Applicant: MICRON TECHNOLOGY, INC., BOISE, ID (US)

(72) Inventors: Hayato Oishi, Hachioji (JP); Hiroki Hosaka, Sagamihara (JP); Makoto Saito, Akita-shi (JP); Moe Ishimatsu, Chofu-shi (JP); Maya Hashimoto, Kawasaki (JP); Wenting Mei, Sagamihara (JP)

(73) Assignee: MICRON TECHNOLOGY, INC., Boise, ID (US)

(21) Appl. No.: 19/347,519

(22) Filed: Oct. 1, 2025

Related U.S. Application Data
(60) Provisional application No. 63/721,271, filed on Nov. 15, 2024.

(51) Int. Cl. H01L 23/528; H01L 23/522; H10B 12/00

(52) U.S. Cl. CPC H10W 20/427; H10W 20/42; H10B 12/00

(57) ABSTRACT

An example apparatus includes a first conductive layer having a plurality of conductive lines extending in a first direction, a second conductive layer located above the first conductive layer and having a plurality of conductive lines extending in a second direction perpendicular to the first direction, and a third conductive layer located above the second conductive layer and having a plurality of conductive lines extending in a third direction inclined with respect to the first and second directions.

### CROSS-REFERENCE TO RELATED APPLICATIONS

This application claims the filing benefit of U.S. Provisional Application No. 63/721,271, filed Nov. 15, 2024. This application is incorporated by reference herein in its entirety and for all purposes.

### BACKGROUND

In a semiconductor device such as a DRAM, a low-resistance redistribution layer called iRDL (inline redistribution layer) may be formed as an uppermost wiring layer in which an external terminal is arranged. By connecting the iRDL to an internal wiring layer located below it at a plurality of portions, the resistance of the internal wiring layer is made low.

### BRIEF DESCRIPTION OF THE DRAWINGS

FIG. 1 is a block diagram showing a circuit configuration of a semiconductor device according to an embodiment of the present disclosure;

FIG. 2 is a schematic cross-sectional view for explaining a structure of the semiconductor device according to the embodiment of the present disclosure;

FIG. 3 is a schematic diagram for explaining extending directions of wiring patterns included in wiring layers;

FIG. 4A is a schematic plan view showing portions of ground wiring patterns included in an iRDL;

FIG. 4B is a schematic plan view showing portions of power wiring patterns included in the iRDL;

FIG. 4C is a schematic plan view showing both the ground wiring patterns shown in FIG. 4A and the power wiring patterns shown in FIG. 4B;

FIG. 5 is an enlarged perspective view of a region B in FIG. 4A;

FIG. 6 is a schematic plan view showing an example of a relation between a plurality of memory mats constituting a memory cell array and the iRDL;

FIG. 7 is a schematic diagram for explaining an example of coupling relations between the ground wiring patterns and the power wiring patterns, and a wiring layer located below thereof;

FIGS. 8A to 8C are schematic plan views showing portions of three types of power wiring patterns in a case where the iRDL includes those power wiring patterns; and

FIG. 8D is a schematic plan view showing all the power wiring patterns shown in FIGS. 8A to 8C.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

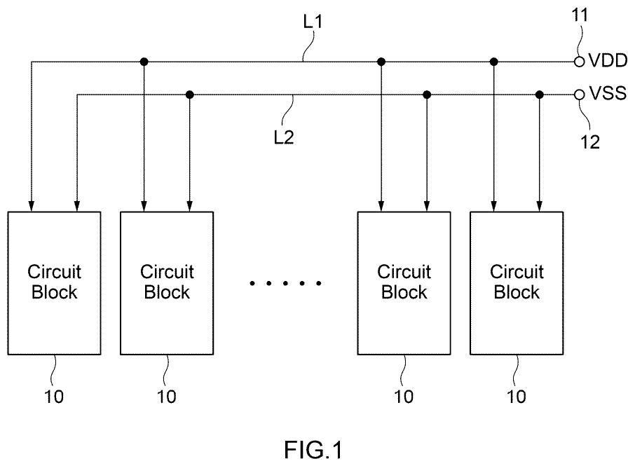

FIG. 1 is a block diagram showing a circuit configuration of a semiconductor device according to an embodiment of the present disclosure. The semiconductor device shown in FIG. 1 includes a plurality of circuit blocks 10 and power lines L1 and L2 supplying power to the circuit blocks 10. The power line L1 is coupled to a power terminal 11 to which a power potential VDD is supplied, and supplies the power potential VDD to the circuit blocks 10. The power line L2 is coupled to a ground terminal 12 to which a ground potential VSS is supplied, and supplies the ground potential VSS to the circuit blocks 10.

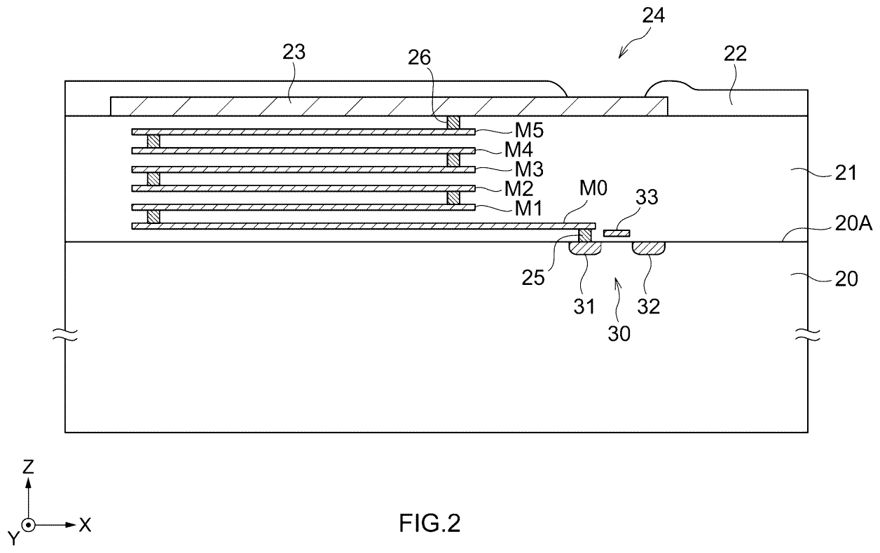

FIG. 2 is a schematic cross-sectional view for explaining a structure of the semiconductor device according to the embodiment of the present disclosure. As shown in FIG. 2, the semiconductor device according to the present embodiment includes a semiconductor substrate 20 and a plurality of wiring layers M0 to M5 stacked via an interlayer dielectric film 21 on a main surface 20A of the semiconductor substrate 20. The main surface 20A of the semiconductor substrate 20 constitutes the X-Y plane. The wiring layers M0 to M5 are stacked in the Z-direction on the main surface 20A of the semiconductor substrate 20 and all extend parallel to the main surface 20A of the semiconductor substrate 20. On the semiconductor substrate 20, a transistor 30 is formed. The transistor 30 includes a source region 31, a drain region 32, and a gate electrode 33. The wiring layer M0 is located lowermost, and a portion thereof may be coupled to the source region 31 of the transistor 30 through a via conductor 25. The wiring layer M5 is an internal wiring layer located uppermost, and a portion thereof is coupled to an iRDL (inline redistribution layer) 23 through a via conductor 26. The iRDL 23 is a wiring layer located above the wiring layer M5, and the wiring width and the wiring thickness thereof are five times or more, for example, about ten times those of the wiring layer M5. Therefore, the resistance value of the iRDL 23 is ⅕ or less, for example, about 1/10 of the resistance values of the wiring layers M4 and M5. The most part of the iRDL 23 is covered by a protection film 22. A portion of the iRDL 23 is exposed from the protection film 22 and is used as an external terminal 24. In general, the upper the wiring layer is, the wiring width and the wiring thickness of each of the wiring layers M0 to M5 are larger.

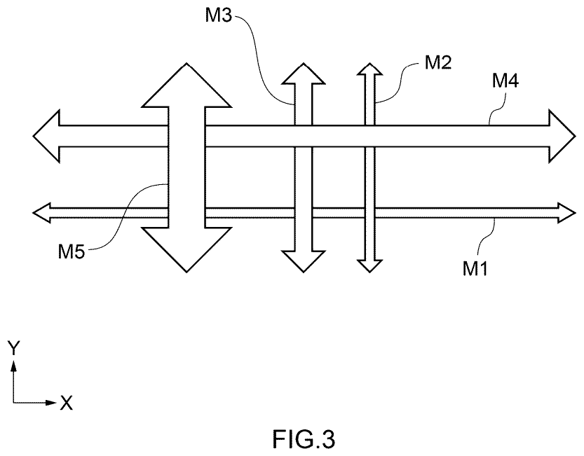

FIG. 3 is a schematic diagram for explaining extending directions of wiring patterns included in the wiring layers M0 to M5. In the example shown in FIG. 3, the wiring patterns formed in the wiring layers M1 and M4 extend mainly in the X-direction, and the wiring patterns formed in the wiring layers M2, M3, and M5 extend mainly in the Y-direction.

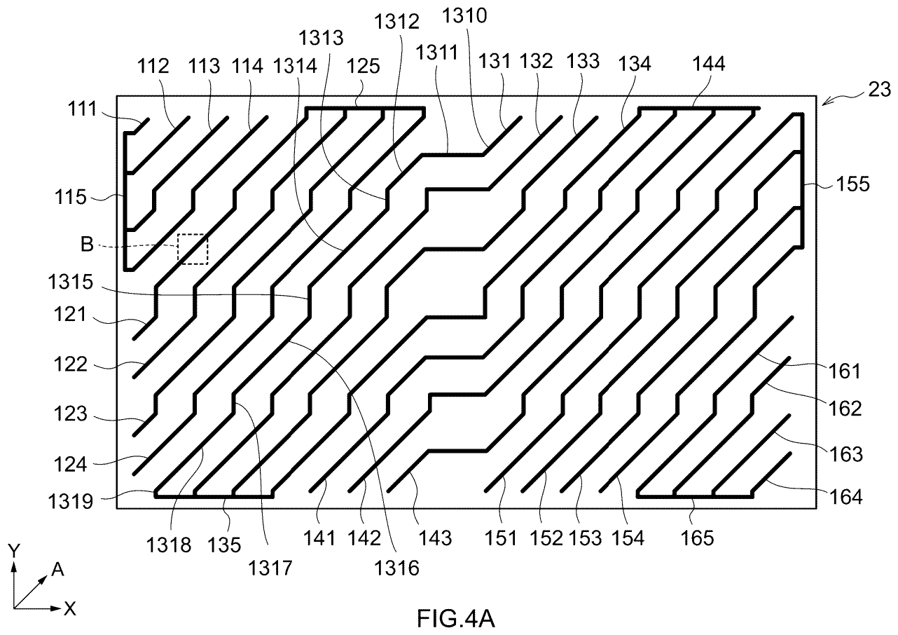

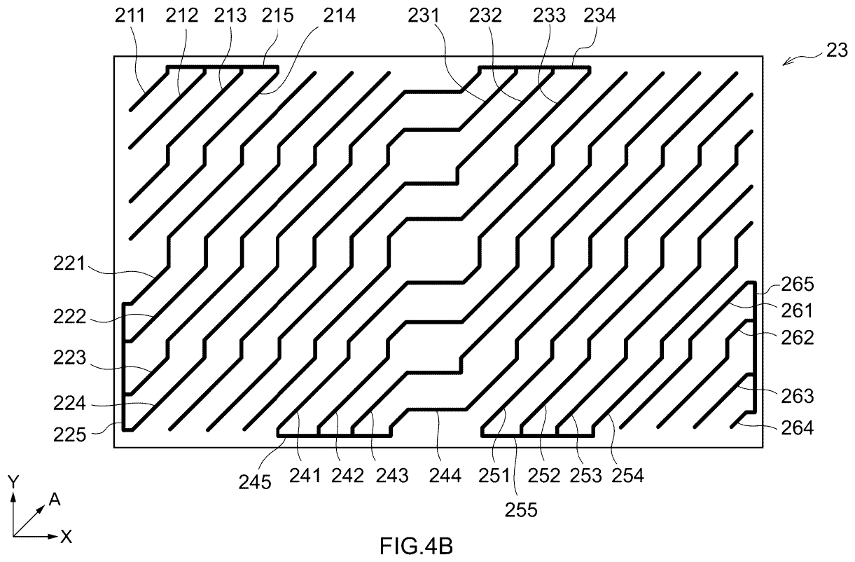

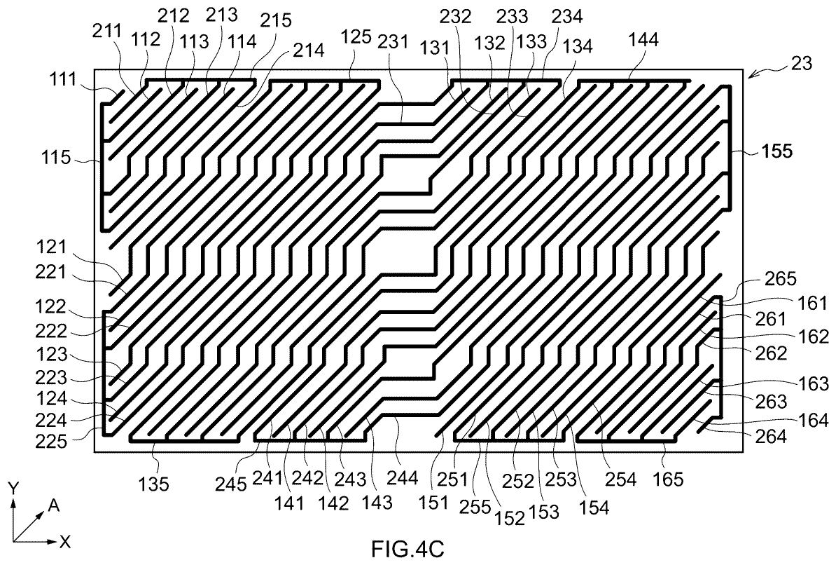

FIG. 4A is a schematic plan view showing portions of ground wiring patterns included in the iRDL 23. The ground wiring patterns included in the iRDL 23 constitute portions of the power line L2 shown in FIG. 1 and supply the ground potential VSS to the circuit blocks 10.

As shown in FIG. 4A, ground wiring patterns 111 to 115, 121 to 125, 131 to 135, 141 to 144, 151 to 155, and 161 to 165 are included in the iRDL 23. Among them, the ground wiring patterns 111 to 114, 121 to 124, 131 to 134, 141 to 143, 151 to 154, and 161 to 164 extend mainly in the A-direction. The A-direction is a direction inclined in a diagonal direction with respect to the X-direction and the Y-direction. The A-direction may be at an angle of 45° with respect to the X-direction. The ground wiring patterns 111 to 114, 121 to 124, 131 to 134, 141 to 143, 151 to 154, and 161 to 164 do not necessarily have to extend in the A-direction over all sections, and may extend in the X-direction in a certain section or extend in the Y-direction in another section. For example, the ground wiring pattern 131 includes sections 1310, 1312, 1314, 1316, and 1318 that extend in the A-direction, a section 1311 extending in the X-direction, and sections 1313, 1315, 1317, and 1319 that extend in the Y-direction. The sections 1310 to 1319 are arranged in this order.

One ends of the ground wiring patterns 111 to 114 are coupled to the ground wiring pattern 115 extending in the Y-direction in common. The other ends of the ground wiring patterns 111 to 114 may be open. One ends of the ground wiring patterns 121 to 124 are coupled to the ground wiring pattern 125 extending in the X-direction in common. The other ends of the ground wiring patterns 121 to 124 may be open. One ends of the ground wiring patterns 131 to 134 are coupled to the ground wiring pattern 135 extending in the X-direction in common. The other ends of the ground wiring patterns 131 to 133 may be open. The other end of the ground wiring pattern 134 and one ends of the ground wiring patterns 141 to 143 are coupled to the ground wiring pattern 144 extending in the X-direction in common. The other ends of the ground wiring patterns 141 to 143 may be open. One ends of the ground wiring patterns 151 to 154 are coupled to the ground wiring pattern 155 extending in the Y-direction in common. The other ends of the ground wiring patterns 151 to 154 may be open. One ends of the ground wiring patterns 161 to 164 are coupled to the ground wiring pattern 165 extending in the X-direction in common. The other ends of the ground wiring patterns 161 to 164 may be open. As described above, most of the ground wiring patterns are coupled at one ends to a ground wiring pattern extending in the X-direction or the Y-direction, and the ground wiring pattern 134 is coupled at one end to the ground wiring pattern 135 extending in the X-direction and at the other end to the ground wiring pattern 144 extending in the X-direction.

As shown in FIG. 4A, the sections extending in the Y-direction of the ground wiring patterns 113, 114, 121 to 124, 131 to 134, 141 to 143, 151, and 152 are arranged in the X-direction. The sections extending in the Y-direction of the ground wiring patterns 121 to 124, 131 to 134, 141 to 143, and 151 to 154 are arranged in the X-direction. The sections extending in the Y-direction of the ground wiring patterns 123, 124, 131 to 134, 141 to 143, 151 to 154, 161, and 162 are arranged in the X-direction. Further, the sections extending in the X-direction of the ground wiring patterns 131 to 134 and 141 to 143 are arranged in the Y-direction.

FIG. 4B is a schematic plan view showing portions of power wiring patterns included in the iRDL 23. The power wiring patterns included in the iRDL 23 constitute portions of the power wiring L1 shown in FIG. 1 and supply the power potential VDD to the circuit blocks 10.

As shown in FIG. 4B, the iRDL 23 includes power wiring patterns 211 to 215, 221 to 225, 231 to 234, 241 to 245, 251 to 255, and 261 to 265. Among them, the power wiring patterns 211 to 214, 221 to 224, 231 to 233, 241 to 244, 251 to 254, and 261 to 264 extend mainly in the A-direction. The power wiring patterns 211 to 214, 221 to 224, 231 to 233, 241 to 244, 251 to 254, and 261 to 264 do not necessarily have to extend in the A-direction over all sections, and may extend in the X-direction in a certain section and in the Y-direction in another section.

One ends of the power wiring patterns 211 to 214 are coupled to the power wiring pattern 215 extending in the X-direction in common. The other ends of the power wiring patterns 211 to 214 may be open. One ends of the power wiring patterns 221 to 224 are coupled to the power wiring pattern 225 extending in the Y-direction in common. The other ends of the power wiring patterns 221 to 223 may be open. The other end of the power wiring pattern 224 and one ends of the power wiring patterns 231 to 233 are coupled to the power wiring pattern 234 extending in the X-direction in common. The other ends of the power wiring patterns 231 to 233 may be open. One ends of the power wiring patterns 241 to 244 are coupled to the power wiring pattern 245 extending in the X-direction in common. The other ends of the power wiring patterns 241 to 244 may be open. One ends of the power wiring patterns 251 to 254 are coupled to the power wiring pattern 255 extending in the X-direction in common. The other ends of the power wiring patterns 251 to 254 may be open. One ends of the power wiring patterns 261 to 264 are coupled to the power wiring pattern 265 extending in the Y-direction in common. The other ends of the power wiring patterns 261 to 264 may be open. As described above, most of the power wiring patterns are coupled at one ends to a power wiring pattern extending in the X-direction or the Y-direction, and the power wiring pattern 224 is coupled at one end to the power wiring pattern 225 extending in the Y-direction and at the other end to the power wiring pattern 234 extending in the X-direction.

As shown in FIG. 4B, the sections extending in the Y-direction of the power wiring patterns 213, 214, 221 to 224, 231, 233, 241 to 244, 251, and 252 are arranged in the X-direction. The sections extending in the Y-direction of the power wiring patterns 221 to 224, 231 to 233, 241 to 244, and 251 to 254 are arranged in the X-direction. The sections extending in the Y-direction of the power wiring patterns 223, 224, 231 to 233, 241 to 244, 251 to 254, 261, and 262 are arranged in the X-direction. Further, the sections extending in the X-direction of the power wiring patterns 224, 231 to 233, and 241 to 244 are arranged in the Y-direction.

FIG. 4C is a schematic plan view showing portions of wiring patterns included in the iRDL 23 and shows both the ground wiring patterns shown in FIG. 4A and the power wiring patterns shown in FIG. 4B. As shown in FIG. 4C, the ground wiring patterns 111 to 114, 121 to 124, 131 to 134, 141 to 143, 151 to 154, and 161 to 164 and the power wiring patterns 211 to 214, 221 to 224, 231 to 233, 241 to 244, 251 to 254, and 261 to 264 are alternately arranged in the X-direction. For example, the power wiring pattern 211 is arranged between the ground wiring patterns 111 and 112 to be sandwiched between them in the X-direction. Further, the ground wiring pattern 112 is arranged between the power wiring patterns 211 and 212 to be sandwiched between them in the X-direction.

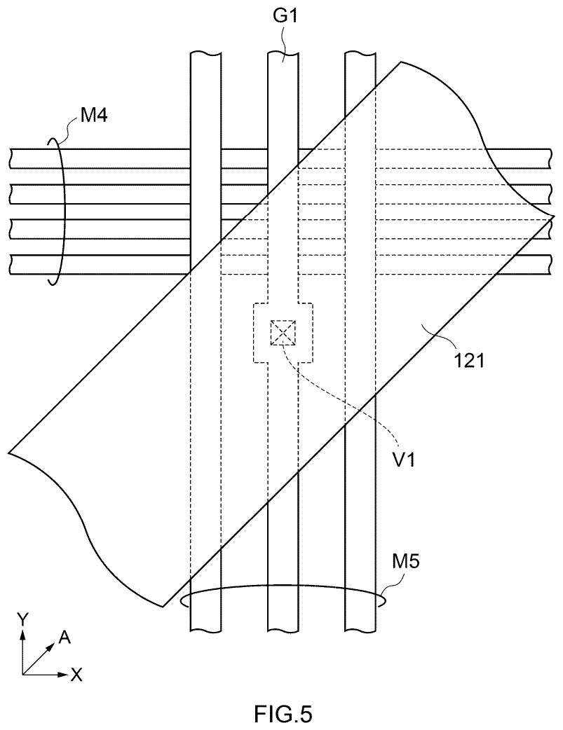

FIG. 5 is an enlarged perspective view of a region B in FIG. 4A. As shown in FIG. 5, the section extending in the A-direction of the ground wiring pattern 121 is coupled to a ground wiring pattern G1 located in the wiring layer M5 through a via conductor V1. Wiring patterns located in the wiring layer M5 extend mainly in the Y-direction. Wiring patterns located in the wiring layer M4 extend mainly in the X-direction. As described above, in the semiconductor device according to the present embodiment, the wiring patterns located in the wiring layer M4 extend mainly in the X-direction, the wiring patterns located in the wiring layer M5 covering the wiring layer M4 extend mainly in the Y-direction, and the wiring patterns located in the iRDL 23 covering the wiring layer M5 extend mainly in the A-direction. This configuration allows the wiring patterns extending mainly in the A-direction in the iRDL 23 to be short-circuited not only via a wiring pattern extending in the X-direction but also via a wiring pattern extending in the Y-direction. For example, the ground wiring patterns 111 to 114 shown in FIG. 4A are short-circuited via the ground wiring pattern 115 extending in the Y-direction, and the ground wiring patterns 121 to 124 shown in FIG. 4A are short-circuited via the ground wiring pattern 125 extending in the X-direction. In addition, since the wiring patterns located in the iRDL 23 include not only the sections extending in the A-direction but also the sections extending in the X-direction or the Y-direction, it is not necessary to largely change the layout of via conductors used for coupling to the wiring layer M5 that is an underlying layer.

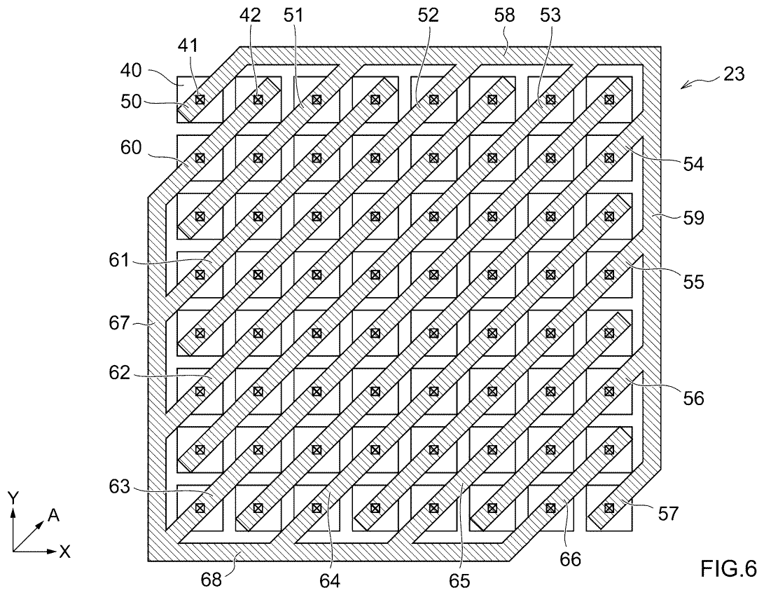

FIG. 6 is a schematic plan view showing an example of a relation between a plurality of memory mats 40 constituting a memory cell array and the iRDL 23 in a case where the semiconductor device according to the present embodiment is a memory device such as a DRAM. In the example shown in FIG. 6, a plurality of ground wiring patterns 50 to 59 and a plurality of power wiring patterns 60 to 68 are provided in the iRDL 23 to overlap the memory mats 40 arranged in matrix in the X-direction and the Y-direction.

The ground wiring patterns 50 to 57 and the power wiring patterns 60 to 66 both extend in the A-direction and are alternately arranged in a comb-like pattern. Any one of the ground wiring patterns 50 to 57 or the power wiring patterns 60 to 66 passes substantially at the center of each of the memory mats 40. A via conductor 41 coupled to the corresponding one of the ground wiring patterns 50 to 57 or a via conductor 42 coupled to the corresponding one of the power wiring patterns 60 to 66 is arranged substantially at the center of each of the memory mats 40.

The ground wiring pattern 58 extends in the X-direction in the outside of a region where the memory mats 40 are provided and is coupled to one ends of the ground wiring patterns 50 to 53 in common. The ground wiring pattern 59 extends in the Y-direction in the outside of the region where the memory mats 40 are provided and is coupled to one ends of the ground wiring patterns 54 to 57 in common. The ground wiring pattern 58 and the ground wiring pattern 59 are coupled to each other. The other ends of the ground wiring patterns 50 to 57 may be open. The power wiring pattern 67 extends in the Y-direction in the outside of the region where the memory mats 40 are provided and is coupled to one ends of the power wiring patterns 60 to 63 in common. The power wiring pattern 68 extends in the X-direction in the outside of the region where the memory mats 40 are provided and is coupled to one ends of the power wiring patterns 63 to 66 in common. The power wiring pattern 67 and the power wiring pattern 68 are coupled to each other. The other ends of the power wiring patterns 60 to 66 may be open.

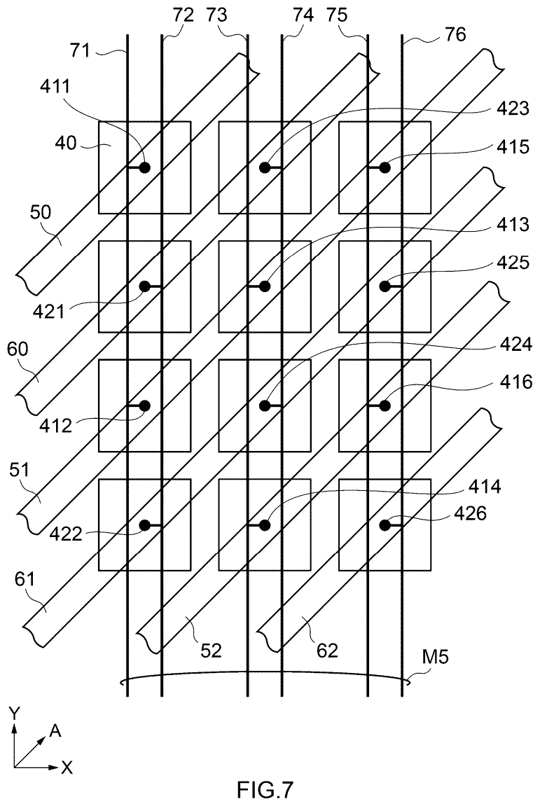

FIG. 7 is a schematic diagram for explaining an example of coupling relations between the ground wiring patterns 50 to 52 and the power wiring patterns 60 to 62, and the wiring layer M5. In the example shown in FIG. 7, ground wiring patterns 71, 73, and 75 and power wiring patterns 72, 74, and 76 are provided in the wiring layer M5. The ground wiring pattern 71 and the power wiring pattern 72 extend in the Y-direction on the memory mats 40 arranged in the Y-direction. The ground wiring pattern 73 and the power wiring pattern 74 extend in the Y-direction on the memory mats 40 arranged in the Y-direction. The ground wiring pattern 75 and the power wiring pattern 76 extend in the Y-direction on the memory mats 40 arranged in the Y-direction.

The ground wiring pattern 50 is coupled to the ground wiring pattern 71 through a via conductor 411. The power wiring pattern 60 is coupled to the power wiring patterns 72 and 74 through via conductors 421 and 423, respectively. The ground wiring pattern 51 is coupled to the ground wiring patterns 71, 73, and 75 through via conductors 412, 413, and 415, respectively. The power wiring pattern 61 is coupled to the power wiring patterns 72, 74, and 76 through via conductors 422, 424, and 425, respectively. The ground wiring pattern 52 is coupled to the ground wiring patterns 73 and 75 through via conductors 414 and 416, respectively. The power wiring pattern 62 is coupled to the power wiring pattern 76 through a via conductor 426. Accordingly, the via conductors 421 and 423 to which the power potential is supplied are arranged in the A-direction, the via conductors 412, 413, and 415 to which the ground potential is supplied are arranged in the A-direction, the via conductors 422, 424, and 425 to which the power potential is supplied are arranged in the A-direction, and the via conductors 414 and 416 to which the ground potential is supplied are arranged in the A-direction.

As described above, in the semiconductor device according to the present embodiment, a plurality of ground wiring patterns and a plurality of power wiring patterns both extending in the A-direction inclined with respect to the X-direction and the Y-direction are provided in an iRDL located at the uppermost layer. Therefore, it is possible to short-circuit the ground wiring patterns to each other or the power wiring patterns to each other by a pattern extending in the X-direction, and it is also possible to short-circuit them by a pattern extending in the Y-direction. Consequently, flexibility in design of the iRDL is increased, and the resistance of power mesh can be made lower.

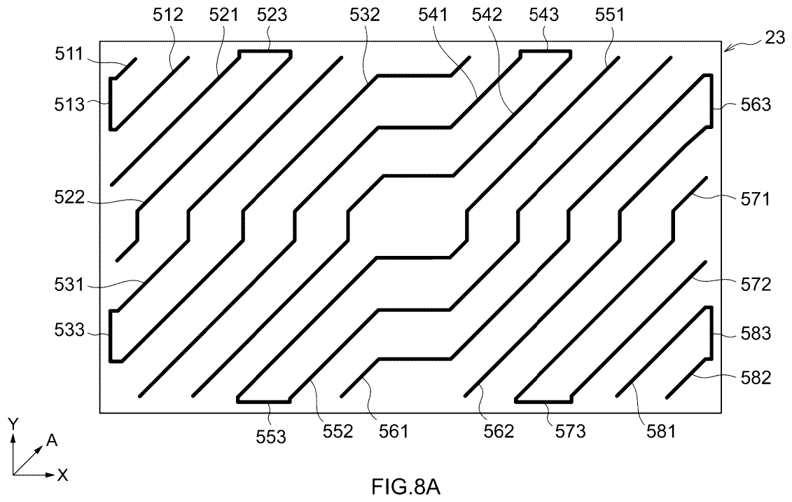

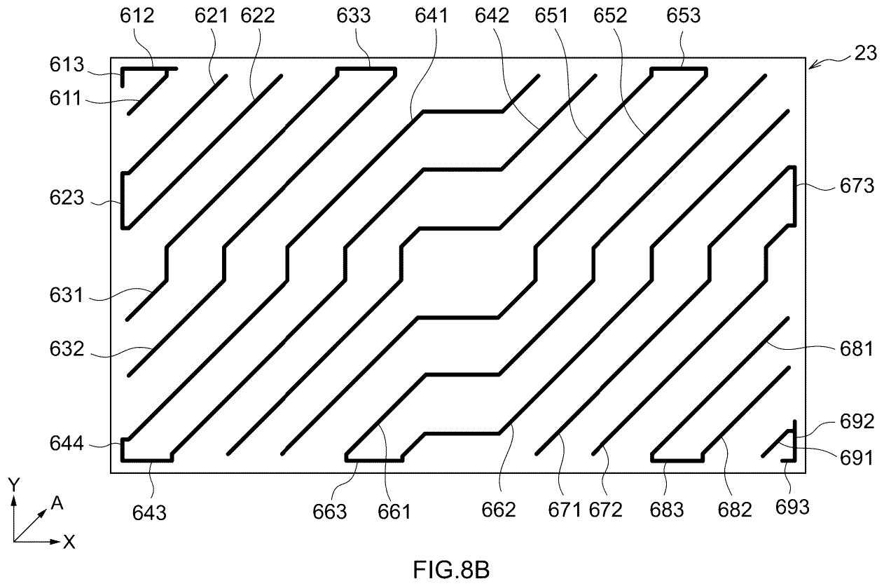

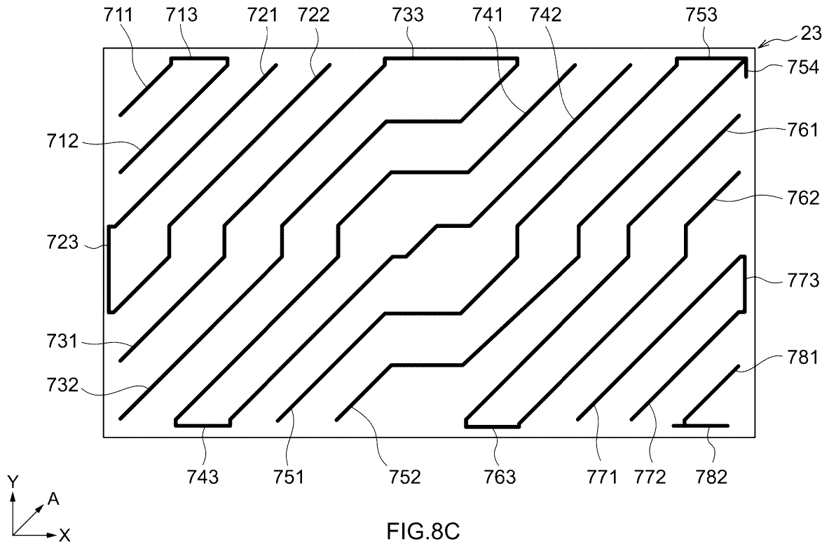

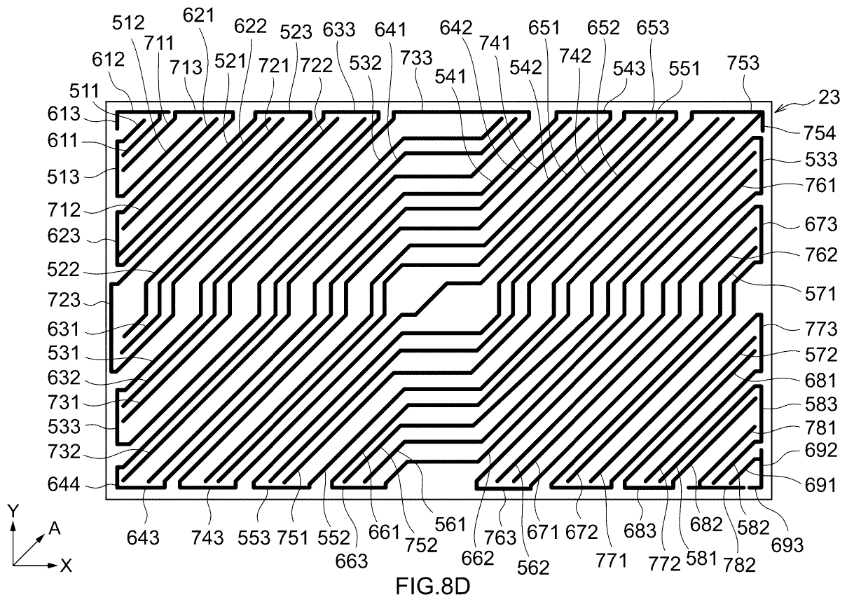

FIGS. 8A to 8C are schematic plan views showing portions of three types of power wiring patterns in a case where the iRDL 23 includes those power wiring patterns. FIG. 8A shows ground wiring patterns to which the ground potential VSS is supplied, FIG. 8B shows power wiring patterns to which the power potential VDD is supplied, and FIG. 8C shows ground wiring patterns to which another power potential VDD2 is supplied.

In the example shown in FIG. 8A, the iRDL 23 includes ground wiring patterns 511 to 513, 521 to 523, 531 to 533, 541 to 543, 551 to 553, 561 to 563, 571 to 573, and 581 to 583. Among them, the ground wiring patterns 511, 512, 521, 522, 531, 532, 541, 542, 551, 552, 561, 562, 571, 572, 581, and 582 extend mainly in the A-direction. One ends of the ground wiring patterns 511 and 512 are coupled to the ground wiring pattern 513 extending in the Y-direction in common. One ends of the ground wiring patterns 521 and 522 are coupled to the ground wiring pattern 523 extending in the X-direction in common. One ends of the ground wiring patterns 531 and 532 are coupled to the ground wiring pattern 533 extending in the Y-direction in common. One ends of the ground wiring patterns 541 and 542 are coupled to the ground wiring pattern 543 extending in the X-direction in common. One ends of the ground wiring patterns 551 and 552 are coupled to the ground wiring pattern 543 extending in the X-direction in common. One ends of the ground wiring patterns 561 and 562 are coupled to the ground wiring pattern 563 extending in the Y-direction in common. One ends of the ground wiring patterns 571 and 572 are coupled to the ground wiring pattern 573 extending in the X-direction in common. One ends of the ground wiring patterns 581 and 582 are coupled to the ground wiring pattern 583 extending in the Y-direction in common.

As shown in FIG. 8A, sections extending in the Y-direction of the ground wiring patterns 522, 531, 532, 541, 542, 551, 552, 561, 562, and 571 are arranged in the X-direction. Sections extending in the X-direction of the ground wiring patterns 532, 541, 542, 551, 552, and 561 are arranged in the Y-direction.

In the example shown in FIG. 8B, the iRDL 23 includes power wiring patterns 611 to 613, 621 to 623, 631 to 633, 641 to 644, 651 to 653, 661 to 663, 671 to 673, 681 to 683, and 691 to 693. Among them, the power wiring patterns 611, 621, 622, 631, 632, 641, 642, 651, 652, 661, 662, 671, 672, 681, 682, and 691 extend mainly in the A-direction. One end of the power wiring pattern 611 is coupled to the power wiring pattern 612 extending in the X-direction. The power wiring pattern 612 is coupled to the power wiring pattern 613 extending in the Y-direction. One ends of the power wiring patterns 621 and 622 are coupled to the power wiring pattern 623 extending in the Y-direction in common. One ends of the power wiring patterns 631 and 632 are coupled to the power wiring pattern 633 extending in the X-direction in common. One end of the power wiring pattern 641 is coupled to the power wiring pattern 644 extending in the Y-direction, and one end of the power wiring pattern 642 is coupled to the power wiring pattern 643 extending in the X-direction. The power wiring pattern 643 and the power wiring pattern 644 are coupled to each other. One ends of the power wiring patterns 651 and 652 are coupled to the power wiring pattern 653 extending in the X-direction in common. One ends of the power wiring patterns 661 and 662 are coupled to the power wiring pattern 663 extending in the X-direction in common. One ends of the power wiring patterns 671 and 672 are coupled to the power wiring pattern 673 extending in the Y-direction in common. One ends of the power wiring patterns 681 and 682 are coupled to the power wiring pattern 683 extending in the X-direction in common. One end of the power wiring pattern 691 is coupled to the power wiring pattern 692 extending in the Y-direction. The power wiring pattern 692 is coupled to the power wiring pattern 693 extending in the X-direction.

As shown in FIG. 8B, sections extending in the Y-direction of the power wiring patterns 631, 632, 641, 642, 651, 652, 661, 662, 671, and 672 are arranged in the X-direction. Sections extending in the X-direction of the power wiring patterns 641, 642, 651, 652, 661, and 662 are arranged in the Y-direction.

In the example shown in FIG. 8C, the iRDL 23 includes power wiring patterns 711 to 713, 721 to 723, 731 to 733, 741 to 743, 751 to 754, 761 to 763, 771 to 773, 781, and 782. Among them, the power wiring patterns 711, 712, 721, 722, 731, 732, 741, 742, 751, 752, 761, 762, 771, 772, and 781 extend mainly in the A-direction. One ends of the power wiring patterns 711 and 712 are coupled to the power wiring pattern 713 extending in the X-direction in common. One ends of the power wiring patterns 721 and 722 are coupled to the power wiring pattern 723 extending in the Y-direction in common. One ends of the power wiring patterns 731 and 732 are coupled to the power wiring pattern 733 extending in the X-direction in common. One ends of the power wiring patterns 741 and 742 are coupled to the power wiring pattern 743 extending in the X-direction in common. One ends of the power wiring patterns 751 and 752 are coupled to the power wiring pattern 753 extending in the X-direction in common. The power wiring pattern 753 is coupled to the power wiring pattern 754 extending in the Y-direction. One ends of the power wiring patterns 761 and 762 are coupled to the power wiring pattern 763 extending in the X-direction in common. One ends of the power wiring patterns 771 and 772 are coupled to the power wiring pattern 773 extending in the Y-direction in common. One end of the power wiring pattern 781 is coupled to the power wiring pattern 782 extending in the X-direction.

As shown in FIG. 8C, sections extending in the Y-direction of the power wiring patterns 722, 731, 732, 741, 751, 752, 761, and 762 are arranged in the X-direction. Sections extending in the X-direction of the power wiring patterns 732, 741, 742, 751, and 752 are arranged in the Y-direction.

FIG. 8D is a schematic plan view showing portions of wiring patterns included in the iRDL 23 and shows all the power wiring patterns shown in FIGS. 8A to 8C. As shown in FIG. 8D, the ground wiring patterns 511, 512, 521, 522, 531, 532, 541, 542, 551, 552, 561, 562, 571, 572, 581, and 582, the power wiring patterns 611, 621, 622, 631, 632, 641, 642, 651, 652, 661, 662, 671, 672, 681, 682, and 691, and the power wiring patterns 711, 712, 721, 722, 731, 732, 741, 742, 751, 752, 761, 762, 771, 772, and 781 are arranged in the X-direction in turn.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first conductive layer having a plurality of conductive lines extending in a first direction;
a second conductive layer located above the first conductive layer and having a plurality of conductive lines extending in a second direction perpendicular to the first direction; and
a third conductive layer located above the second conductive layer and having a plurality of conductive lines extending in a third direction inclined with respect to the first and second directions.

2. The apparatus of claim 1,
wherein the plurality of conductive lines in the second conductive layer includes first and second conductive lines extending in the second direction,
wherein the plurality of conductive lines in the third conductive layer includes a third conductive line extending in the third direction,
wherein the first conductive line is coupled to the third conductive line through a first via conductor,
wherein the second conductive line is coupled to the third conductive line through a second via conductor, and
wherein the first and second via conductors are arranged in the third direction.

3. The apparatus of claim 2,
wherein the plurality of conductive lines in the third conductive layer further includes a fourth conductive line extending in the third direction,
wherein the first conductive line is coupled to the fourth conductive line through a third via conductor,
wherein the second conductive line is coupled to the fourth conductive line through a fourth via conductor, and
wherein the third and fourth via conductors are arranged in the third direction.

4. The apparatus of claim 3,
wherein the plurality of conductive lines in the third conductive layer further includes a fifth conductive line coupled in common to the third and fourth conductive lines, and
wherein the fifth conductive line extends in one of the first and second directions.

5. The apparatus of claim 3,
wherein the first and third via conductors are arranged in the second direction, and
wherein the second and fourth via conductors are arranged in the second direction.

6. The apparatus of claim 5,
wherein the plurality of conductive lines in the second conductive layer further includes a fifth conductive line extending in the second direction,
wherein the fifth conductive line is coupled to the fourth conductive line through a fifth via conductor, and
wherein the first and fifth via conductors are arranged in the first direction.

7. The apparatus of claim 6,
wherein the plurality of conductive lines in the third conductive layer further includes a sixth conductive line extending in the third direction and arranged between the third and fourth conductive lines,
wherein the third and fourth conductive lines are supplied with a first power potential, and
wherein the sixth conductive line is supplied with a second power potential different from the first power potential.

8. The apparatus of claim 7,
wherein the plurality of conductive lines in the second conductive layer further includes seventh and eighth conductive lines extending in the second direction,
wherein the sixth conductive line is coupled to the seventh conductive line through a sixth via conductor,
wherein the sixth conductive line is coupled to the eighth conductive line through a seventh via conductor,
wherein the sixth via conductor is arranged between the first and third via conductors in the second direction, and
wherein the seventh via conductor is arranged between the second and fourth via conductors in the second direction.

9. The apparatus of claim 8, wherein the seventh via conductor is arranged between the first and fifth via conductors in the first direction.

10. The apparatus of claim 2, wherein the third conductive line includes a first section extending in the third direction, a second section extending in the third direction, and a third section coupled between the first and second sections and extending in one of the first and second directions.

11. The apparatus of claim 10, wherein the third conductive line further includes a fourth section extending in the third direction and a fifth section coupled between the second and fourth sections and extending in another of the first and second directions.

12. The apparatus of claim 1, wherein the third wiring layer is an uppermost wiring layer.

13. The apparatus of claim 12, wherein the third wiring layer is a redistribution layer.

14. An apparatus comprising an uppermost wiring layer,
wherein the uppermost wiring layer includes:
a first conductive line extending in a first direction;
a second conductive line extending in one of the first direction and a second direction perpendicular to the first direction;
a plurality of third conductive lines each having a first section extending in a third direction inclined with respect to the first and second directions; and
a plurality of fourth conductive lines each having a second section extending in the third direction,
wherein one end of the first section of each of the plurality of third conductive lines is coupled to the first conductive line, and
wherein one end of the second section of each of the plurality of fourth conductive lines is coupled to the second conductive line.

15. The apparatus of claim 14, wherein the plurality of third conductive lines and the plurality of fourth conductive lines are alternately arranged.

16. The apparatus of claim 15,
wherein the plurality of third conductive lines are supplied with a first power potential, and
wherein the plurality of fourth conductive lines are supplied with a second power potential different from the first power potential.

17. The apparatus of claim 14,
wherein each of the plurality of third conductive lines further has a third section extending in the first direction, and
wherein each of the plurality of fourth conductive lines further has a fourth section extending in the first direction.

18. The apparatus of claim 17, wherein the third section of each of the plurality of third conductive lines and the fourth section of each of the plurality of fourth conductive lines are arranged in the second direction.

19. An apparatus comprising:
a memory cell array including a plurality of memory mats arranged in matrix; and
a voltage supply mesh-wiring structure above the memory cell array, the voltage supply mesh-wiring structure having:
a plurality of first wirings in a first wiring layer, each of the plurality of first wirings extending in a first direction over corresponding ones of the plurality of memory mats arranged in the first direction;
a plurality of second wirings in a second wiring layer above the first wiring layer, each of the plurality of second wirings extending in a second direction, which is substantially perpendicular to the first direction, over corresponding ones of the plurality of memory mats arranged in the second direction; and
a plurality of third wirings in a third wiring layer above the second wiring layer, each of the plurality of third wirings extending, at least in part, in a third direction over corresponding ones of the plurality of memory mats arranged in a diagonal direction.

20. The apparatus of claim 19, wherein the third wiring layer is a redistribution layer.

21. The apparatus of claim 20, wherein a thickness of the third wiring layer is five times or more a thickness of the second wiring layer.

22. The apparatus of claim 20, wherein a resistance of the third wiring layer is ⅕ or less of a resistance of the second wiring layer.
